(19) United States
(12) Patent Application Publication
(10) Pub. No.: US 2013/0292779 A1
(43) Pub. Date: Nov. 7, 2013

(54) SEMICONDUCTOR DEVICE AND SEMICONDUCTOR DEVICE PRODUCTION PROCESS

(71) Applicant: FUJITSU SEMICONDUCTOR LIMITED, Yokohama-shi (JP)

(72) Inventor: Masaki Okuno, Akiruno (JP)

(73) Assignee: FUJITSU SEMICONDUCTOR LIMITED, Yokohama-shi (JP)

(21) Appl. No.: 13/853,807

(22) Filed: Mar. 29, 2013

(30) Foreign Application Priority Data
May 7, 2012 (JP) 2012-105606

(51) Int. Cl. H01L 27/088; H01L 21/8238

(52) U.S. Cl. CPC H01L 27/0886; H01L 21/823821
USPC 257/369; 438/154

(57) ABSTRACT

A semiconductor device includes a first p-channel FET, the first p-channel FET includes: a first fin-type semiconductor region; a first gate electrode crossing the first fin-type semiconductor region and defining a first p-channel region at an intersection of the first fin-type semiconductor region and the first gate electrode; p-type first source/drain regions, each formed on either side of the first gate electrode in the first fin-type semiconductor region; and first and second compressive stress generating regions formed by oxidizing regions located outside the p-type first source/drain regions in the first fin-type semiconductor region.

### CROSS-REFERENCE TO RELATED APPLICATION

This application is based upon and claims the benefit of priority of the prior Japanese Patent Application No. 2012-105606, filed on May 7, 2012, the entire contents of which are incorporated herein by reference.

### FIELD

The embodiments discussed herein are related to a semiconductor device and a semiconductor device production process.

### BACKGROUND

Development of a field effect transistor (FET) having a fin-type structure is under way. A FET having a fin-type structure, which is generally referred to as a Fin-FET or a double gate Fin-FET, is a three-dimensional field effect transistor with the surface of the channel perpendicular to the surface of the substrate. In its structure, there are thin wall- (fin-)like protrusions perpendicular to the surface of the substrate, with gate insulating films and gate electrodes formed on both sidewalls of a fin, and source/drain regions formed on the fin on both sides of the gates.

A field effect transistor having a fin-type structure can reduce the area size it occupies on the substrate because the channel surfaces are perpendicular to the surface of the substrate and can suppress the short channel effect easily because gate electrodes are located on both sides of the channel, making it highly adaptable to miniaturization and high-speed operation.

For FETs, a structure which improves the mobility of carriers by using a stress is generally known. In an n-channel FET, applying a tensile stress in the channel length direction, or the direction parallel to the channel, improves the mobility of electrons. In a p-channel FET, applying a compressive stress in the channel length direction, or the direction parallel to the channel, improves the mobility of holes.

The known methods to apply a stress to a channel include one in which a liner layer of a nitride film or the like having a stress is formed so as to cover a FET and one in which a recess is formed on a silicon substrate and an alloy semiconductor of crystals with different lattice constants such as SiGe and SiC is embedded in it. Also for a fin-type FET, there are proposals of a configuration in which a liner film for applying a stress is formed and a configuration in which a recess is formed and an alloy semiconductor of crystals with different lattice constants is embedded in it (e.g., U.S. Pat. No. 7,388,259, and U.S. Pat. No. 7,709,312).

In addition, there is a proposal of a structure which is produced by forming an expandable or contractible stress film, such as SiGe and ozone TEOS film, on at least either the upper or the lower portion of a fin, patterning it together with the fin, forming gate electrodes on both sides and the upper surface of the fin with a gate insulating film interposed in between, and then expanding or contracting the stress film by oxidizing the stress film to apply a stress to the fin in the height direction, or the direction perpendicular to the channel (e.g., Japanese Unexamined Patent Application Publication No. 2009-259865).

### SUMMARY

According to one aspect of the present invention, a semiconductor device includes a first p-channel FET, the first p-channel FET includes: a first fin-type semiconductor region; a first gate electrode crossing the first fin-type semiconductor region and defining a first p-channel region at an intersection of the first fin-type semiconductor region and the first gate electrode; p-type first source/drain regions, each formed on either side of the first gate electrode in the first fin-type semiconductor region; and first and second compressive stress generating regions formed by oxidizing regions located outside the p-type first source/drain regions in the first fin-type semiconductor region.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are plan views schematically illustrating the configuration of a fin-type semiconductor device having p-channel FETs and n-channel FETs according to an embodiment.

FIGS. 2A to 2I are perspective and cross section views to explain a production process of a p-channel fin-type FET.

FIGS. 3A to 3F are perspective views to explain a production process of forming a p-channel FET by using an SOI substrate.

FIGS. 4A and 4B are plan views illustrating an arrangement example for forming a plurality of fin-type FETs.

### DESCRIPTION OF EMBODIMENTS

In a semiconductor device having a fin-type structure, a fin (thin plate) shaped silicon region with, for example, a fin width of 20 to 30 nm and a fin length of several hundred nm is disposed perpendicular to a support substrate.

The inventor has studied a configuration produced by selectively oxidizing a fin-type silicon region to apply a compressive stress to adjacent regions. A fin-type silicon region with a thickness of about 30 nm can be can be oxidized across its entire thickness by oxidizing from both sides. When silicon is oxidized into silicon oxide, the volume is expanded. If a fin-type silicon region is oxidized in a height-directional stripe pattern at two positions along the length direction, the silicon region sandwiched by the two oxidized stripe regions receive a compressive stress along the fin length direction due to volume expansion caused by oxidation.

By forming a gate electrode structure that crosses the fin-type silicon region, a FET that flows current in the fin length direction is formed. At this time, the channel length (gate length) direction is the fin length direction. The compressive stress along the fin length direction works as a compressive stress in the channel length direction, that is, the direction parallel to the channel, which has a function of improving the p-channel FET characteristics (the mobility of holes).

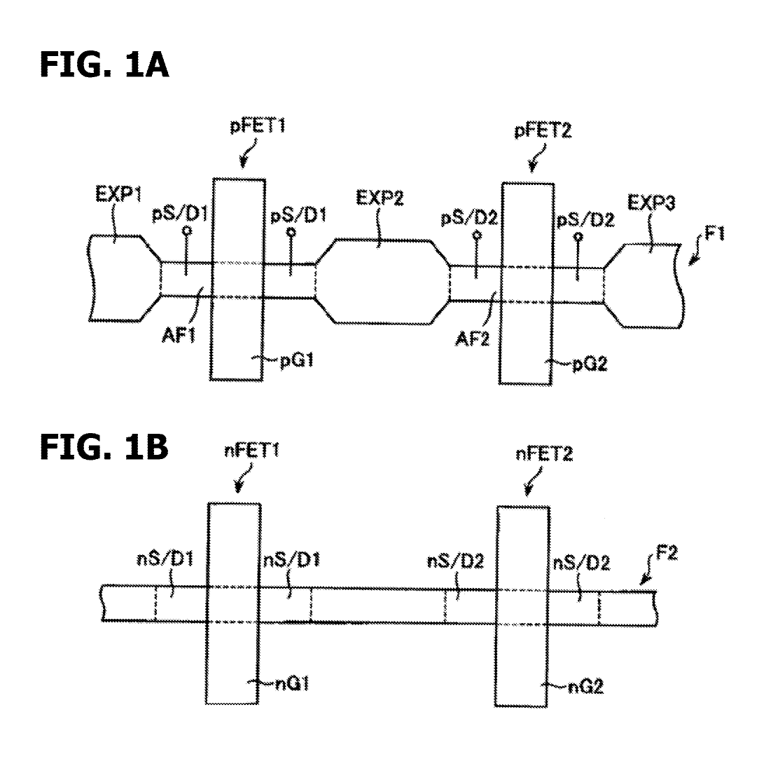

FIGS. 1A and 1B are plan views illustrating the basic configuration according to embodiment 1. On an underlying substrate, an n-type silicon fin region F1 and a p-type silicon fin region F2 are located.

Refer to FIG. 1A. p-type gate structures pG1 and pG2 are formed so as to cross the n-type silicon fin region F1. By adding p-type impurities to the fin regions on both sides of the p-type gate structure pG1, a first pair of p-type source/drain regions pS/D1 are formed. In the same manner, by adding p-type impurities to the fin region on both sides of the p-type gate structure pG2, a second pair of p-type source/drain regions pS/D2 are formed. Thus, a basic configuration of the p-channel FETs, pFET1 and pFET2, is formed.

The n-type silicon fin region F1 is oxidized at positions sandwiching the p-channel FETs (three positions in the figure) and expanded regions EXP1, EXP2, and EXP3 are formed. The active fin region AF1 sandwiched by expanded regions EXP1 and EXP2 and the active fin region AF2 sandwiched by expanded regions EXP2 and EXP3 receive a compressive stress along the fin length direction. The p-type gates pG1 and pG2 are formed so as to cross the active fin regions AF1 and AF2. In the active fin regions AF1 and AF2 under the gate electrodes, the mobility of holes is improved due to the compressive stress in the gate length (channel length) direction, resulting in the improvement of characteristics of the p-channel FETs.

Refer to FIG. 1B. With respect to the p-type silicon fin region F2, n-type gate structures nG1 and nG2 are formed so as to cross the fin region F2 and defines the channel regions of n-channels FET nFET1 and nFET2. Impurities of n-type are added to the fin regions on both sides of the n-type gate structure nG1 to form a first pair of n-type source/drain regions nS/D1. In the same manner, n-type impurities are added to the fin regions on both sides of the n-type gate structure nG2 to form a second pair of n-type source/drain regions nS/D2.

Because a compressive stress in the gate length (channel length) direction degrades the mobility of electrons for an n-channel FET, an oxide region is not formed on either side of the n-channel FET nFET. The structures of a p-channel FET and an n-channel FET are asymmetric.

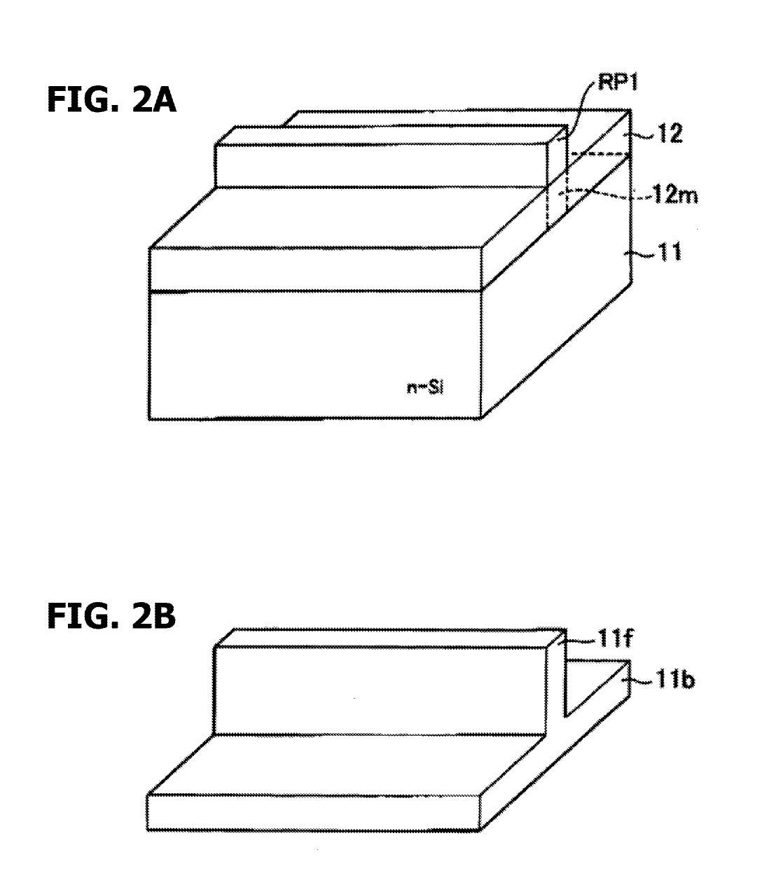

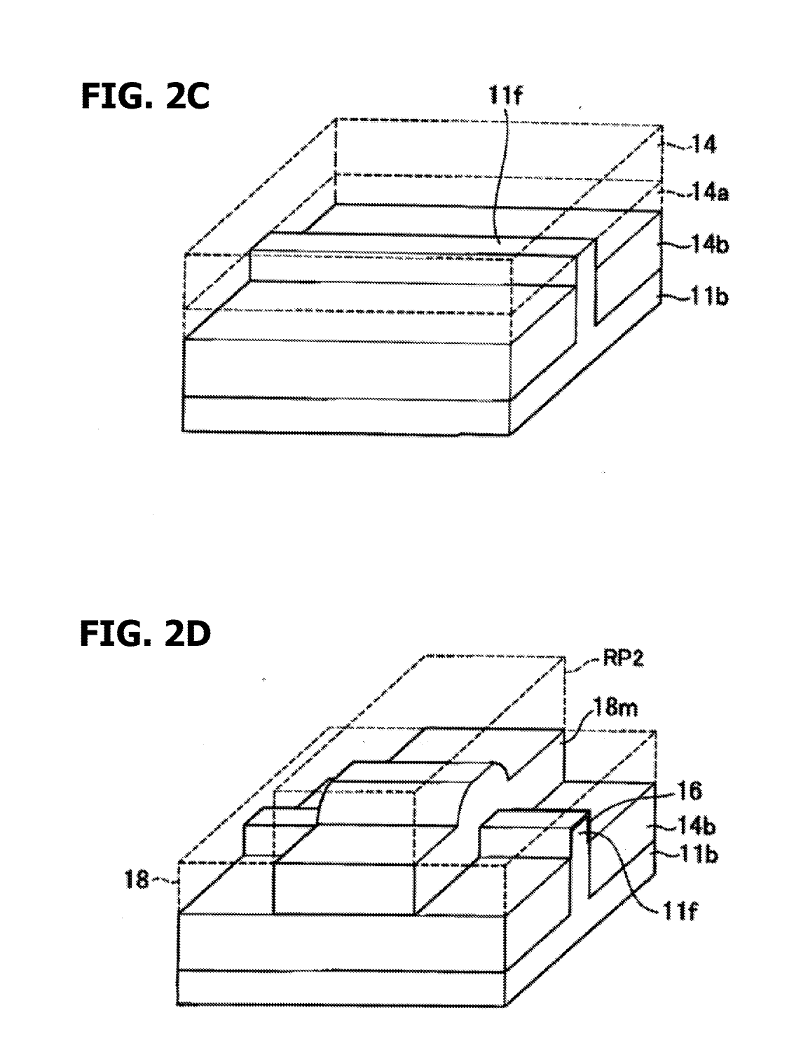

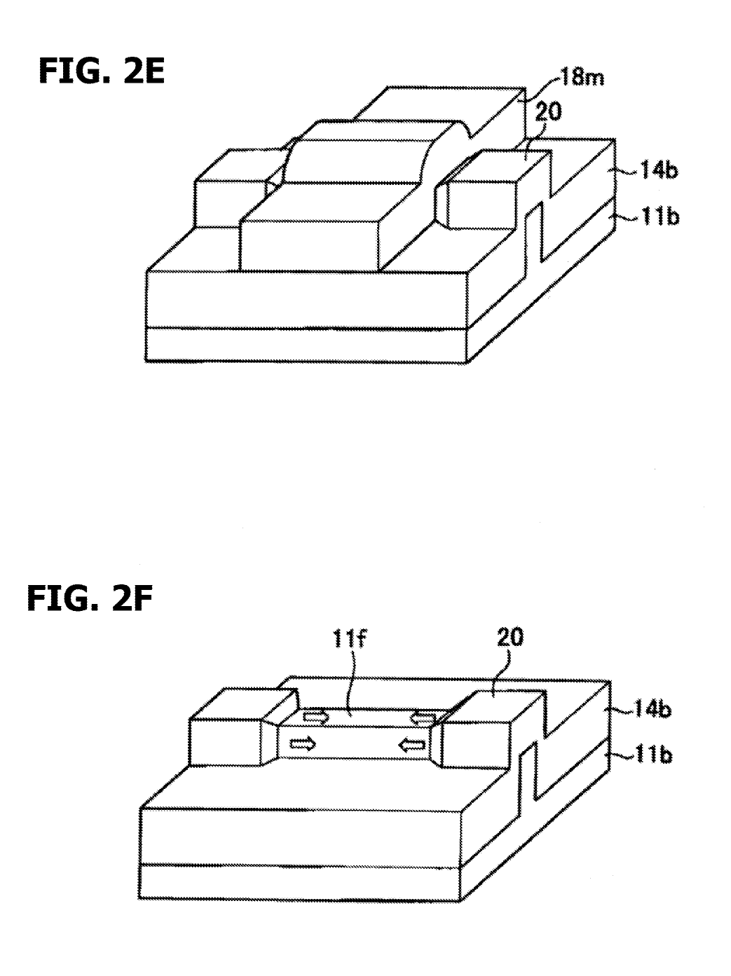

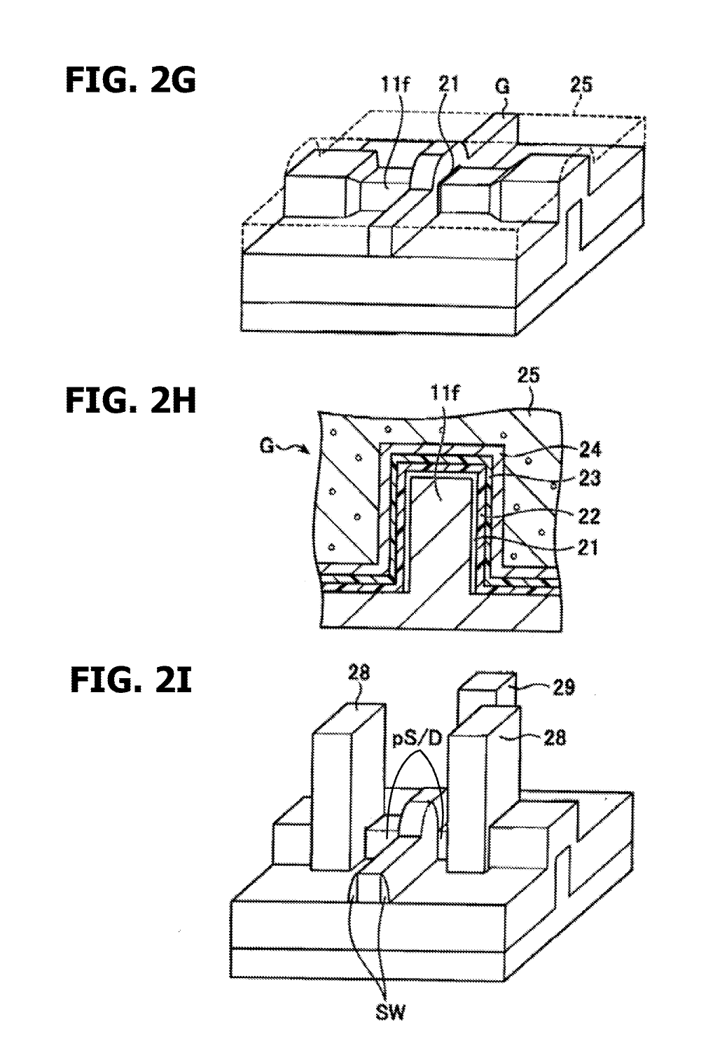

The production process of a p-channel fin-type FET according to embodiment 1 is described below with reference to FIGS. 2A to 2I.

As illustrated in FIG. 2A, an about 10 to 50 nm thick silicon oxide film 12 for hard mask is deposited on the surface of an n-type Si substrate 11 with chemical vapor deposition (CVD). The silicon oxide film 12 is coated with a photoresist layer, exposed and developed to form a photoresist pattern RP1 to pattern a fin structure. With the photoresist pattern RP1 used as an etching mask, a hard mask layer 12 is etched with reactive ion etching (RIE) using CF-containing gas (e.g., CF₄, CHF₃, C₄F₈) to form a hard mask 12m. The silicon substrate 11 outside the hard mask 12m is etched with RIE using a mixed gas including CF-containing gas, HBr, and oxygen. The silicon fin to be formed is, for example, 20 nm in width and 200 to 300 nm in depth.

FIG. 2B illustrates a schematic view of a fin structure formed by etching. A silicon fin structure 11f is formed on a support substrate 11b. The length of the fin structure 11f along the surface of the support substrate 11b is not limited in particular. For example, a length to contain a plurality of p-channel FETs may be adopted.

As illustrated in FIG. 2C, an insulating film 14 is deposited by plasma CVD so as to embed the silicon fin structure 11f. For example, a phosphosilicate glass (PSG) film is deposited by using a mixed gas of silane or disilane as a Si source, oxygen as an O source, and phosphine as a P source. For example, a PSG film with a thickness of 400 nm or more is deposited to embed the silicon fin 11f.

Chemical mechanical polishing (CMP) is performed for the top surface of the insulating film 14 to flatten the surface of the insulating film 14 and expose the top face of the silicon fin structure 11f (state in 14a). Next, the silicon oxide film 14 is etched by wet etching using a dilute hydrofluoric acid solution or dry etching using a C₄F₈—Ar mixed gas to expose the silicon fin structure 11f, with the surface of the support substrate 11b covered with an insulating film 14b. The degree of etching (the height of the silicon fin structure 11f exposed) is, for example, 100 to 150 nm. The lower portion of the silicon fin structure 11f is embedded and the silicon oxide film 14b that extends over the support substrate 11b functions as an element separation region.

As illustrated in FIG. 2D, performing thermal oxidation is performed so that an oxide film liner 16 with a thickness of about 5 to 10 nm is formed over the exposed surface of the silicon fin structure 11f that extends upward from the silicon oxide film 14b. To cover the silicon fin structure over which an oxide film liner 16 is formed, a nitride silicon film 18 with a thickness of 10 to 50 nm is deposited by CVD using a mixed gas of disilane and ammonia. The nitride silicon film 18 is an insulating film functioning as an antioxidant film for protection against oxidizing species such as oxygen and ozone.

On the nitride silicon film 18, a photoresist pattern RP2 having a shape that covers a FET forming region is formed and the nitride silicon film 18 is etched by RIE using, for example, a CHF₃/Ar/O₂ mixed gas to pattern an antioxidant mask 18m. The region deprived of the nitride film 18 defines the opening for the oxidation process. Considering the formation of a so-called bird's beak caused by penetration of oxidizing species below the edge of the oxidation mask, the antioxidation mask 18m is slightly larger than the region where a FET is formed. After that, the photoresist pattern RP2 is removed.

As illustrated in FIG. 2E, thermal oxidation is performed for the silicon fin structure 11f exposed out of the antioxidation mask 18m to convert the silicon region into an silicon oxide region. Thermal oxidation is performed at 900 to 1,000° C. in a dry oxygen atmosphere. If wet oxidation is performed for the thermal oxidation in this step, reaction with a nitride silicon film generates ammonia, which may be dispersed to the silicon fin and cause defects, and therefore, dry oxidation is preferable. The silicon fin 11f exposed out of the antioxidation mask 18m is oxidized and an oxide (silicon oxide) region 20 is formed.

As illustrated in FIG. 2F, the antioxidation mask 18m is removed. The silicon nitride film is etched and removed by wet etching with hot phosphoric acid or reactive ion etching (RIE) with a CHF₃/Ar/O₂ mixed gas. The exposed oxide film liner 16 is removed by wet etching with dilute hydrofluoric acid or dry etching. The volume of the oxide region 20 is expanded. The silicon fin region 11f sandwiched by the volume-expanded oxide regions 20 is pushed from both sides and receives a compressive stress.

As illustrated in FIG. 2G, a gate oxide film 21 is formed by, for example, performing thermal oxidation of the surface of the silicon fin region 11f. Alternately, another insulating film such as high-k insulating film may be deposited, as required, to work in combination as a gate insulating film. A gate electrode layer 25 of polycrystalline silicon is deposited so as to surround the silicon fin region with the gate insulating film interposed, and patterned by using a photoresist mask or the like to form a gate electrode structure G. It is also possible to adopt a polycide gate and a metal gate.

FIG. 2H is a schematic cross section view of a gate electrode structure adopting a high-k film and a metal gate. On the surface of the silicon fin region 11f, for example, a silicon oxide film 21 with a thickness of 1 nm or less is formed; a high-k film 22 such as hafnium oxide film with a thickness of 1 nm is deposited thereon; and a cap layer 23 such as an alumina film with a thickness of 1 nm is formed thereon. On the cap layer 23, a metal gate layer 24 such as TiN layer with a thickness of 3 to 10 nm is formed and a polysilicon layer 25 with a thickness of 50 nm is deposited thereon. A mask with a gate width is formed and a gate electrode G is patterned by etching. After gate electrode patterning, ion implantation of a p-type impurity such as boron is performed for the silicon fin region 11f on both sides of the gate electrode G to form p-type extension regions.

As illustrated in FIG. 2I, an insulating film such as silicon oxide film covering the gate electrode is deposited, and the insulating film on the flat region is removed by anisotropic etching such as reactive ion etching (RIE) so as to leave a sidewall spacer SW. After that, high-concentration ion implantation of a p-type impurity such as boron is performed on the silicon fin region on both sides of the sidewall spacer SW to form high-concentration p-type source/drain regions pS/D. After each ion implantation step, or after finishing a plurality of ion implantation steps, rapid thermal annealing (RTA), spike annealing, millisecond annealing, etc. are performed to activate the ion-implanted impurities. As necessary, the contact resistance is reduced by performing a silicide process to form a contact electrode. Extraction electrodes 28 are formed on the source/drain regions and extraction electrodes 29 are formed on the gate electrodes.

Thus, in the p-channel FET, oxide regions are formed by oxidizing the silicon fin region outside the FET regions (source/drain regions). Volume expansion occurs and a compressive stress is applied in the gate length direction of the channel, making it possible to improve the mobility of holes.

It is to be understood that the above configuration is not restrictive. For example, it is possible to use, for example, an SOI substrate made by bonding a silicon layer via a silicon oxide layer.

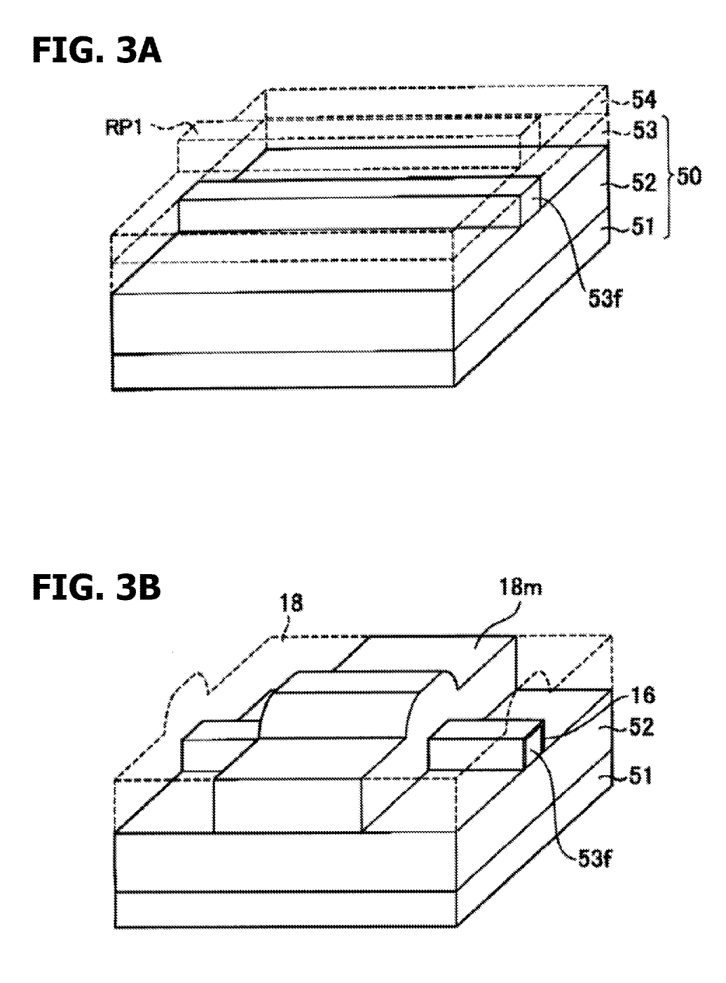

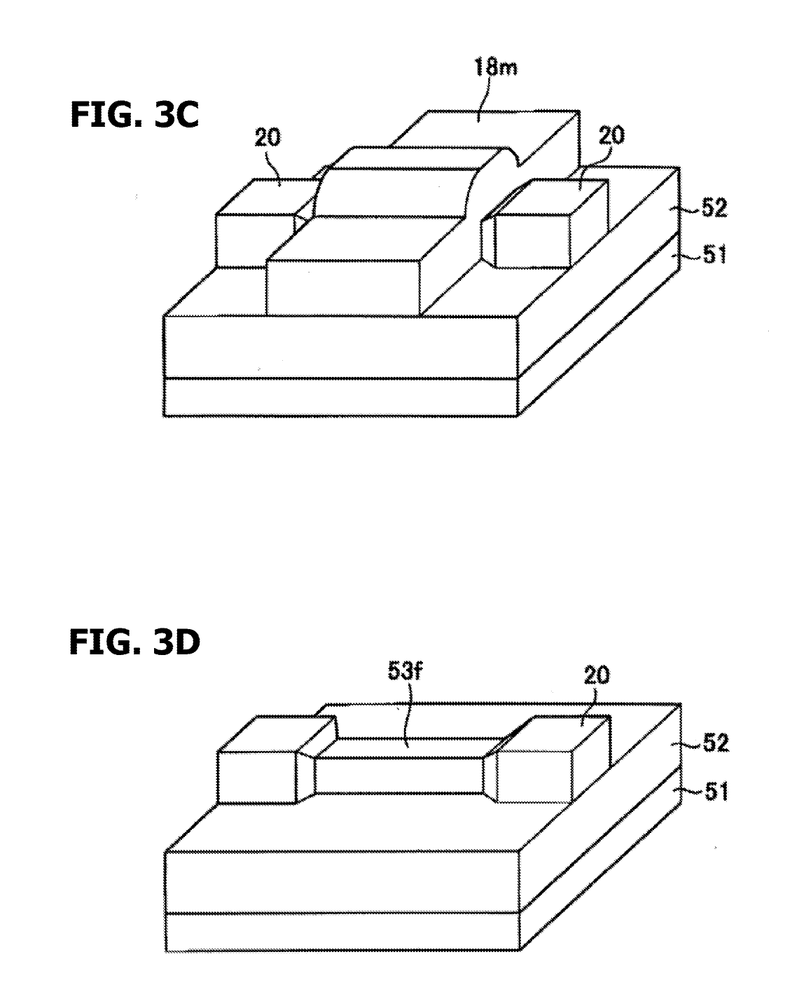

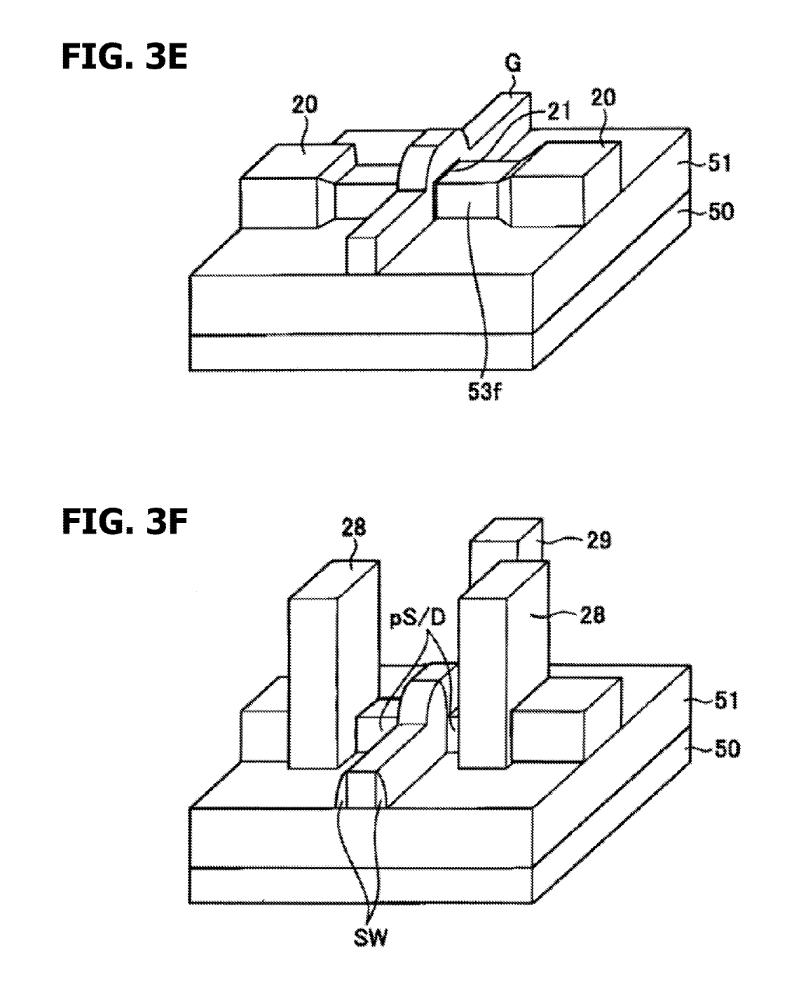

FIGS. 3A to 3F are perspective views illustrating the production process to form a p-channel FET by using an SOI substrate according to embodiment 2.

As illustrated in FIG. 3A, an SOI substrate 50 including an active Si layer 53 coupled to a support Si substrate 51 via a buried silicon oxide (BOX) layer 52 is prepared. As in embodiment 1, a hard mask layer 54 made of silicon oxide or the like is deposited on the SOI substrate 50 and a photoresist pattern RP1 is formed thereon. The hard mask layer 54 is etched using the photoresist pattern RP1 as an etching mask, and the active Si layer 53 is etched using the hard mask layer as a mask to form a silicon fin region 53f. After that, the photoresist pattern RP1 is removed.

Here, a hard mask layer is not an essential requirement. It is also possible to omit the hard mask layer if possible and pattern the silicon fin region by etching the silicon layer using the photoresist pattern as an etching mask. The bottom of the silicon fin region 53f is in contact with the silicon oxide layer 52.

As illustrated in FIG. 3B, an oxide film liner 16 is formed on the surface of the silicon fin region 53f by performing thermal oxidation and a nitride silicon film 18 that covers the oxide film liner 16 and the silicon fin region 53f is deposited. As in embodiment 1, a nitride silicon film 18 is patterned by using a photoresist pattern to produce an antioxidation mask 18m.

As illustrated in FIG. 3C, dry oxidation is performed for the silicon fin region protruded from the antioxidation mask 18m, as in embodiment 1, to form a pair of oxide regions 20 that sandwich the FET region.

As illustrated in FIG. 3D, the antioxidation mask 18m of nitride silicon is removed by the same procedure as in embodiment 1. The silicon fin region 53f sandwiched by the oxide regions 20 receives a compressive stress pushed from both sides.

As illustrated in FIG. 3E, a gate oxide film 21 and, as necessary, other insulating films are formed on the surface of the silicon fin region 53f, and a conductive gate electrode G of poly-silicon or the like that crosses the silicon fin region 53f is formed, as in embodiment 1. Ion implantation of p-type impurity is performed as necessary to form p-type extension regions.

As illustrated in FIG. 3F, an insulating film such as silicon oxide film is deposited and anistropic etching is performed to form a sidewall spacer SW, as in embodiment 1. High concentration p-type impurity implantation is performed to form high concentration p-type source/drain regions pS/D. A silicide process is performed as necessary, and extraction electrodes 28 and 29 are formed.

The fin-type FET created by using an active Si layer of an SOI substrate, which has a complete dielectric isolation structure, is suited for high-speed operation.

To form a CMOS circuit, both pFET and nFET are required. If a pFET and an FET are created on one fin-type semiconductor region, there is a high possibility that a compressive stress is applied also to the nFET. It is preferable that a compressive stress is not generated on the n-channel FET and a compressive stress is generated on the p-channel FET. Therefore, it is preferable that only p-channel FETs are formed on one fin structure collectively while required n-channel FETs are formed on another fin structure.

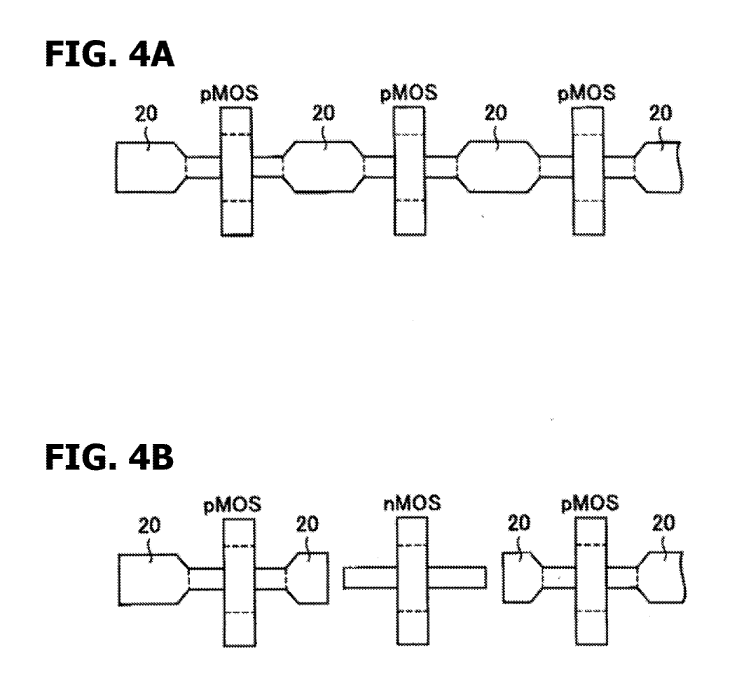

FIG. 4A illustrates a configuration in which a plurality of p-channel FETs are formed on one fin-type silicon region and an oxide region 20 is formed between each pair of adjacent p-channel FETs and outside of the p-channel FET at either end to generate a compressive stress. In this case, only n-channel FETs may be created on another fin-type silicon region collectively, as illustrated in FIG. 1B.

It is also possible to create p-channel FETs and n-channel FETs on one fin-type silicon region.

As illustrated in FIG. 4B, for example, one fin-type silicon region is divided into three sections. Between each section, a disconnected portion is formed on the fin-type silicon region to physically separate each section to release the stress. In the figure, on the fin-type silicon regions located at both ends, a p-channel FET having oxide regions 20 at both ends is formed, while on the fin-type silicon region at the center, an n-channel FET is formed and an oxide region is not formed. The p-channel FETs receive a compressive stress in the channel length direction and the n-channel FET does not receive a compressive stress in the channel length direction.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising a first p-channel FET, the first p-channel FET comprising:
a first fin-type semiconductor region;
a first gate electrode crossing the first fin-type semiconductor region and defining a first p-channel region at an intersection of the first fin-type semiconductor region and the first gate electrode;
p-type first source/drain regions, each formed on either side of the first gate electrode in the first fin-type semiconductor region; and
first and second compressive stress generating regions formed by oxidizing regions located outside the p-type first source/drain regions in the first fin-type semiconductor region.

2. The semiconductor device according to claim 1, further comprising a second p-channel FET, the second p-channel FET comprising:
an extension of the first fin-type semiconductor region extending out of the second compressive stress generating region;
a second gate electrode crossing the extension and defining a second p-channel region at an intersection of the extension and the second gate electrode;
p-type second source/drain regions, each formed on either side of the second gate electrode region in the extension; and
a third compressive stress generating region formed by oxidizing an end portion of the extension located opposite to the second compressive stress generating region with the second gate electrode interposed in between.

3. The semiconductor device according to claim 1, further comprising an n-channel FET, the n-channel FET comprising:
a second fin-type semiconductor region;
a second gate electrode crossing the second fin-type semiconductor region and defining an n-channel region at an intersection of the second fin-type semiconductor region and the second gate electrode; and
n-type second source/drain regions, each formed on either side of the second gate electrode in the second fin-type semiconductor region.

4. The semiconductor device according to claim 2, further comprising an n-channel FET, the n-channel FET comprising:
a second fin-type semiconductor region;
a third gate electrode crossing the second fin-type semiconductor region and defining an n-channel region at an intersection of the second fin-type semiconductor region and the third gate electrode; and
n-type third source/drain regions, each formed on either side of the third gate electrode in the second fin-type semiconductor region.

5. The semiconductor device according to claim 3, wherein
the second fin-type semiconductor region exists on a virtual extension line extending from the first fin-type semiconductor region through the first compressive stress generating region, and
a disconnected portion is formed between the first stress generating region and the second fin-type semiconductor region.

6. A semiconductor device production process comprising:
forming a first fin-type semiconductor region;
forming first and second compressive stress generating regions by oxidizing a first region and a second region separated from the first region in the first fin-type semiconductor region;
forming a first gate electrode crossing the first fin-type semiconductor region and defining a p-channel region at an intersection of the first fin-type semiconductor region and the first gate electrode between the first and second compressive stress generating regions; and
forming a first p-channel FET by forming p-type first source/drain regions, each located either between the p-channel region and the first compressive stress generating region or between the p-channel region and the second compressive stress generating region in the first fin-type semiconductor region.

7. The semiconductor device production process according to claim 6, wherein the first fin-type semiconductor region is a fin-type silicon region and the oxidation is effected by dry oxidation.

8. The semiconductor device production process according to claim 7, wherein the forming a first fin-type semiconductor region comprises:
forming a mask layer on a substrate having a silicon layer;
forming the fin-type silicon region by etching the silicon layer using the mask layer as a mask;
depositing an insulating film covering the fin-type silicon region;
polishing the insulating film to expose a top face of the fin-type silicon region; and
etching the insulating film so that the upper surface of the insulating film becomes lower than the top face of the fin-type silicon region.

9. The semiconductor device production process according to claim 7, wherein the forming a first fin-type semiconductor region comprises:
forming a mask layer on an SOI substrate having an insulating layer and a Si layer on the insulating layer; and
exposing the insulating layer by etching the Si layer using the mask layer as a mask.

10. The semiconductor device production process according to claim 7, wherein the forming first and second compressive stress generating regions comprises:
forming a liner oxide film on the surface of the fin-type silicon region;
depositing on the liner oxide film, an antioxidation insulating film having a function of protection against oxidizing species;
forming an opening for oxidation operation, by etching and removing the antioxidation insulating film in the first region and the second region separated from the first region;
oxidizing by dry oxidation, the first fin-type semiconductor region exposed through the opening for oxidation operation; and
removing the antioxidation insulating film.

11. The semiconductor device production process according to claim 8, wherein the forming first and second compressive stress generating regions comprises:
forming a liner oxide film on the surface of the fin-type silicon region;
depositing on the liner oxide film, an antioxidation insulating film having a function of protection against oxidizing species;
forming an opening for oxidation operation, by etching and removing the antioxidation insulating film in the first region and the second region separated from the first region;
oxidizing by dry oxidation, the first fin-type semiconductor region exposed through the opening for oxidation operation; and
removing the antioxidation insulating film.

12. The semiconductor device production process according to claim 9, wherein the forming first and second compressive stress generating regions comprises:
forming a liner oxide film on the surface of the fin-type silicon region;
depositing on the liner oxide film, an antioxidation insulating film having a function of protection against oxidizing species;
forming an opening for oxidation operation, by etching and removing the antioxidation insulating film in the first region and the second region separated from the first region;
oxidizing by dry oxidation, the first fin-type semiconductor region exposed through the opening for oxidation operation; and
removing the antioxidation insulating film.
